(19) United States
(12) Patent Application Publication
(10) Pub. No.: US 2025/0015029 A1
(43) Pub. Date: Jan. 9, 2025

(54) MULTI-DIE-TO-WAFER HYBRID BONDING

(71) Applicant: Murata Manufacturing Co., Ltd., Nagaokakyo-Shi (JP)

(72) Inventors: Sinan GOKTEPELI, Austin, TX (US); Kouassi Sebastien KOUASSI, San Diego, CA (US); Shishir RAY, San Diego, CA (US); Anil KUMAR, San Diego, CA (US)

(21) Appl. No.: 18/888,811

(22) Filed: Sep. 18, 2024

Related U.S. Application Data
(63) Continuation of application No. PCT/US2023/022773, filed on May 18, 2023.
(60) Provisional application No. 63/346,949, filed on May 30, 2022.

(51) Int. Cl. H01L 23/00; H01L 25/065; H01L 27/092; H01L 29/16; H01L 29/20

(52) U.S. Cl. CPC H01L 24/08; H01L 24/05; H01L 24/80; H01L 25/0657; H01L 27/092; H01L 29/16; H01L 29/2003; H01L 2224/0224; H01L 2224/05557; H01L 2224/08146; H01L 2224/80139; H01L 2224/80895; H01L 2224/80896; H01L 2225/06541

(57) ABSTRACT

Integrated circuit structures and methods for a high precision die-to-wafer bonding technology for fabricating 3-D stacked IC dies. Embodiments include precise alignment structures and methods, and also provide fast fabrication techniques using simultaneous multi-die picking and placing of individual dies from a die-source wafer onto a recipient wafer. Stacked-die yields are improved over wafer-to-wafer bonding technologies by enabling testing and selection of known-good die-source dies before bonding onto the recipient wafer, and by providing optional physical alignment structures on the recipient wafer and/or die-source wafer. Embodiments enable, for example, fabrication of high-power, high-performance devices on ICs formed on GaAs or GaN die-source wafers and bonding individual die-source IC dies to ICs that include CMOS control and driver circuitry formed on an SOI recipient wafer. The resulting 3-D stacked IC dies may offer advantages that include scalability, reliability, and form-factor reduction.

### CROSS-REFERENCE TO RELATED APPLICATIONS

The present application is a continuation of International Application No. PCT/US2023/022773 filed on May 18, 2023, which, in turn, claims priority to U.S. Provisional Application No. 63/346,949, filed on May 30, 2022, for “MULTI-DIE-TO-WAFER HYBRID BONDING,” the contents of all of which are incorporated herein by reference in their entirety.

### TECHNICAL FIELD

The present invention relates to three-dimensional integrated circuit structures and circuits.

### BACKGROUND

The electronics industry continues to strive for ever-increasing electronic functionality and performance in a wide variety of products, including (by way of example only) personal electronics (e.g., “smart” watches and fitness wearables), personal computers, tablet computers, wireless network components, televisions, cable system “set top” boxes, radar systems, and cellular telephones. Increased functionality and/or performance commonly translates to more transistors and other electronic components on an integrated circuit (IC) die. While the number of transistors per unit area of an IC die has increased over time as IC manufacturing process nodes have shrunk device dimensions, the two-dimensional (2-D) planar form-factor or “footprint” of some IC dies has not decreased at the same rate, primarily owing to the use of more (albeit smaller) transistors to implement increased functionality and/or performance. The 2-D footprint of an IC die is one constraint on reducing the size of circuit modules and circuit boards within products.

In order to shrink the 2-D footprint of an IC die, a number of three-dimensional (3-D) technologies have been developed that have focused on stacking and bonding aligned IC dies from different wafers (also known as wafer-to-wafer bonding), stacking and bonding individual IC dies on non-singulated IC dies on a wafer (also known as die-to-wafer bonding), and stacking and bonding an individual IC die on another IC die (also known as die-to-die bonding). Bonding of the two wafers/dies generally uses both dielectric materials (e.g., silicon dioxide, SiCN, SiCOH, and/or analogous alloys) and conductive interconnect materials (e.g., copper, aluminum, and/or their alloys) as bonding elements in a mating engagement. In general, a high density of interconnects between the conjoined wafers/dies is desirable to achieve good communications between them. One such bonding technology may be referred to as “hybrid bonding interconnect” (HBI). HBI technology has a demonstrated high interconnect density, is a planar technology that does not require underfill or carrier wafer integration, and enables formation of interconnects between two IC wafers/dies during a bond annealing stage at relatively low temperatures (e.g., ≤˜450° C.).

A problem with wafer-to-wafer bonding is that defects may be, in the worst case, exactly additive. Thus, for example, if both a recipient wafer and a die-source wafer each exhibit a die defect rate of 10%, when the two wafers are bonded together, the resulting set of bonded dies may have a defect rate of as much as 20%. In addition, the two bonded wafers generally need to be the same size, thus limiting the candidates for die-source wafers. A problem with die-to-die bonding is that manipulating, aligning, and bonding two very small dies is difficult and time consuming. Accordingly, die-to-wafer bonding may be preferred for many applications.

FIG. 1A is a perspective view of a recipient wafer 100 on which multiple individual dies 102 singulated from a different die-source wafer have been affixed using a hybrid bonding interconnect technology. In the illustrated example, the recipient wafer 100 has not yet been singulated, and the gaps between dies 102 include dicing “streets” (also known as dicing “lanes”). FIG. 1B is a top plan view of a single die 104 singulated from the recipient wafer 100, on which is affixed a die 102 from a die-source wafer. Together, the bonded die-source die 102 and recipient-wafer die 104 form a single 3-D stacked IC die. Shown in phantom view are a number of mating conductive interconnections 106 or vias that connect the die-source die 102 to the recipient-wafer die 104.

A problem with current die-to-wafer bonding technologies is that the alignment accuracy is only about 5-10 μm compared to an alignment accuracy of about 1 μm for wafer-to-wafer bonding. Accordingly, there is a need for higher bonding precision for die-to-wafer bonding technologies.

### SUMMARY

The present invention encompasses integrated circuit structures and methods for a high precision die-to-wafer bonding technology for fabricating 3-D stacked IC dies. Embodiments of the present invention include precise alignment structures and methods, and also provide fast fabrication techniques using simultaneous multi-die picking and placing of individual dies from a die-source wafer onto a recipient wafer. Stacked-die yields are improved over wafer-to-wafer bonding technologies by enabling testing and selection of known-good die-source dies before bonding onto the recipient wafer.

The die-source wafer may be made from a compound semiconductor material that may include group III-V semiconductor materials such as gallium arsenide (GaAs), gallium nitride (GaN), and indium phosphide (InP), group II-VI semiconductor materials such as cadmium selenide (CdSe), zinc sulfide (ZnS), and zinc telluride (ZnTe), group I-III-VI semiconductor materials, as well as other compound semiconductor materials. The die-source wafer may alternatively comprise a silicon-based material, including bulk silicon, high-resistivity (HR) silicon, silicon-on-insulator (SOI), and silicon-on-sapphire (SOS).

The recipient wafer may comprise (by way of example only) a compound semiconductor material or a silicon-based material. The recipient wafer and the die-source wafer need not be (but may be) made from the same material, and the die-source wafer may be of a different size (e.g., 150 mm diameter) than the recipient wafer (e.g., 300 mm diameter).

One aspect of the invention is a method of fabricating 3-D stacked integrated circuit (IC) dies, the method including: fabricating die-source IC dies on a die-source wafer; forming conductive vias on a bonding surface of each die-source IC die; singulating the die-source IC dies; testing the die-source IC dies before and/or after singulating the die-source IC dies to determine known-good die-source IC dies; picking known-good die-source IC dies from the singulated dies; and contacting the picked known-good die-source IC dies to corresponding recipient-wafer ICs formed as part of a recipient wafer, thereby bonding the known-good die-source IC dies to the corresponding recipient-wafer ICs on the recipient wafer to form 3-D stacked IC dies.

Embodiments of the present invention enable, for example, fabrication of high-power, high-performance devices on ICs formed on GaAs or GaN die-source wafers and bonding individual die-source IC dies to recipient-wafer ICs that include CMOS control and driver circuitry formed on an SOI recipient wafer. The resulting 3-D stacked IC dies may offer advantages that include scalability, reliability, and form-factor reduction.

The details of one or more embodiments of the invention are set forth in the accompanying drawings and the description below. Other features, objects, and advantages of the invention will be apparent from the description and drawings, and from the claims.

### BRIEF DESCRIPTION OF THE DRAWINGS

FIG. 1A is a perspective view of a recipient wafer on which multiple individual dies singulated from a different die-source wafer have been affixed using a hybrid bonding interconnect technology.

FIG. 1B is a top plan view of a single die singulated from the recipient wafer, on which is affixed a die from a die-source wafer.

FIG. 2A is a cross-sectional view of a set of pre-singulation 3-D stacked IC dies showing individual die-source IC dies bonded to corresponding ICs (indicated by dashed ovals) formed on a recipient wafer.

FIG. 2B is a cross-sectional view of a set of post-singulation 3-D stacked IC dies showing individual die-source IC dies bonded to corresponding ICs (indicated by dashed ovals) formed from the recipient wafer.

FIGS. 3A-3B are a process flow chart showing one method for fabricating the structures shown in FIGS. 2A and 2B.

FIG. 4A is a cross-sectional view of a die-source wafer containing multiple complete fabricated ICs before singulation.

FIG. 4B is a cross-sectional view of a die-source wafer after deposition of a dielectric layer and conductive vias.

FIG. 4C is a cross-sectional view of singulated die-source IC dies adhered to a dicing tape.

FIG. 4D is a cross-sectional view of a die-tape containing multiple die-source IC dies, a “pick and place” apparatus, a plasma source, and a recipient wafer in the early stages of placing die-source IC dies.

FIG. 4E is a cross-sectional view of a recipient wafer 206 on which has been placed multiple die-source IC dies.

FIG. 4F is a cross-sectional view of a recipient wafer on which has been bonded multiple die-source IC dies.

FIG. 4G is a cross-sectional view of a recipient wafer on which has been bonded multiple die-source IC dies encapsulated by a fill material.

FIG. 4H is a cross-sectional view of a set of post-singulation 3-D stacked IC dies showing individual die-source IC dies bonded to corresponding recipient-wafer ICs (indicated by dashed ovals).

FIG. 4I is a top plan view of four die-source IC dies bonded on a single recipient-wafer IC.

FIG. 5A is a cross-sectional view of a recipient wafer having one embodiment of alignment structures designed to guide placement of a die-source IC die with respect to a corresponding recipient-wafer IC.

FIG. 5B is a closeup view of a portion of FIG. 5A.

FIG. 5C is a top plan view of a first embodiment of an alignment structure pattern defining a grid structure that would border and contact all sides of a die-source IC die.

FIG. 5D is a top plan view of a second embodiment of an alignment structure pattern defining edge-engagement structures that would contact only part of the edges of a die-source IC die.

FIG. 5E is a top plan view of a third embodiment of an alignment structure pattern defining corner-engagement structures that would contact only the four corners of a die-source IC die.

FIG. 5F is a top plan view of a fourth embodiment of an alignment structure pattern defining “sparse” corner-engagement structures that would contact only two opposite corners of a die-source IC die.

FIG. 6 is a process flow chart showing one method for forming alignment structures.

FIG. 7 is a cross-sectional view of a die-source IC die and a recipient-wafer IC configured with complementarily-shaped alignment structure projections and depressions.

FIG. 8 is a top plan view of a substrate that may be, for example, a printed circuit board or chip module substrate (e.g., a thin-film tile).

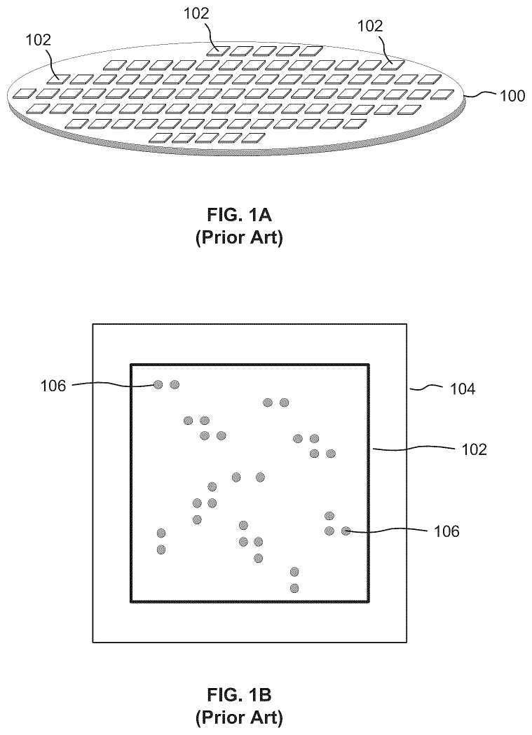

Like reference numbers and designations in the various drawings indicate like elements unless the context requires otherwise.

### DETAILED DESCRIPTION

The present invention encompasses integrated circuit structures and methods for a high precision die-to-wafer bonding technology for fabricating 3-D stacked IC dies. Embodiments of the present invention include precise alignment structures and methods, and also provide fast fabrication techniques using simultaneous multi-die picking and placing of individual dies from a die-source wafer onto a recipient wafer. Stacked-die yields are improved over wafer-to-wafer bonding technologies by enabling testing and selection of known-good die-source dies before bonding onto the recipient wafer.

Embodiments of the present invention enable, for example, fabrication of high-power, high-performance devices on ICs formed on GaAs or GaN die-source wafers and bonding individual die-source IC dies to recipient-wafer ICs that include CMOS control and driver circuitry formed on an SOI recipient wafer. In some other embodiments, recipient-wafers may include only passive devices. The resulting 3-D stacked IC dies may offer advantages that include scalability, reliability, and form-factor reduction.

For purposes of this disclosure, “wafer” includes an initial substrate and further encompasses a substrate on which circuitry, electronic and/or optical components, and/or conductive connections have been formed.

### Example Structure and Method

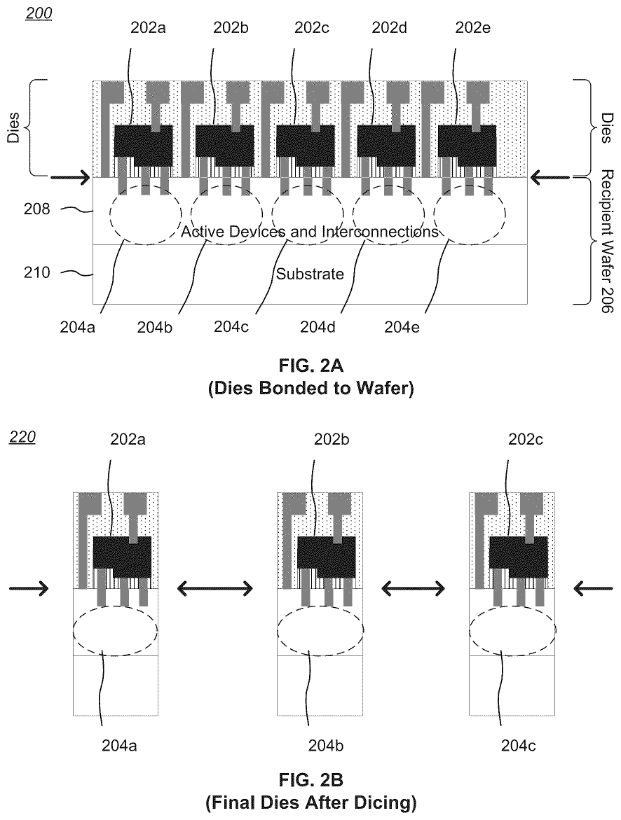

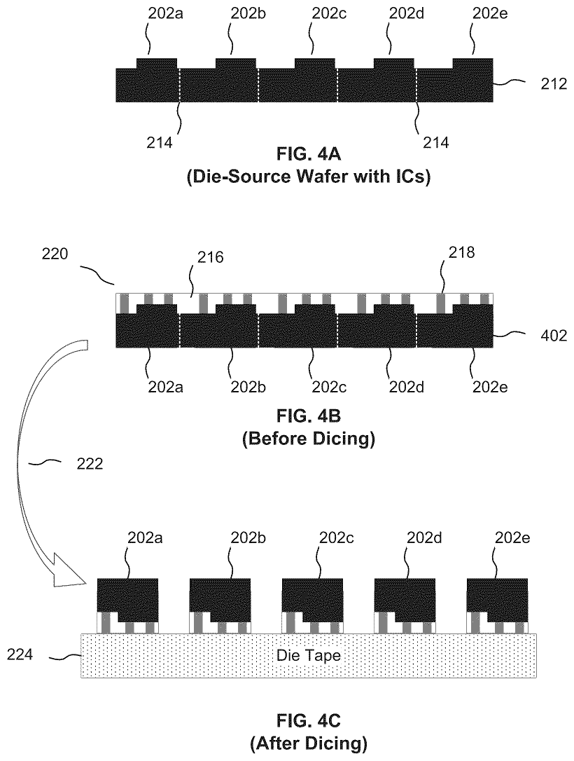

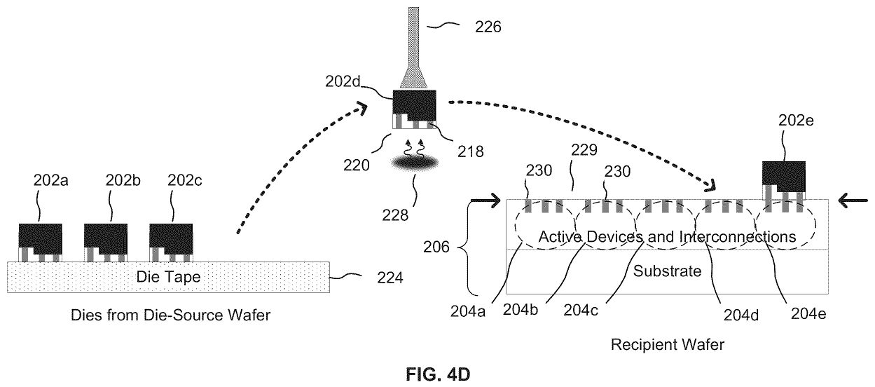

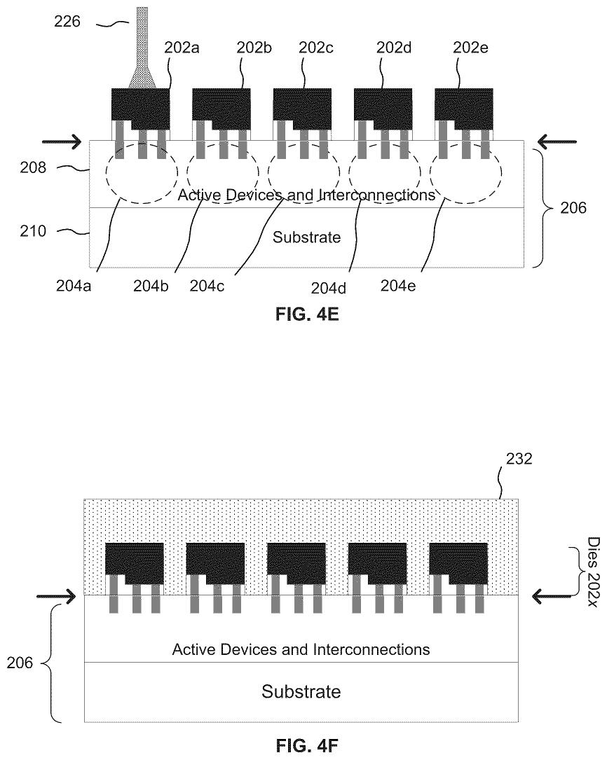

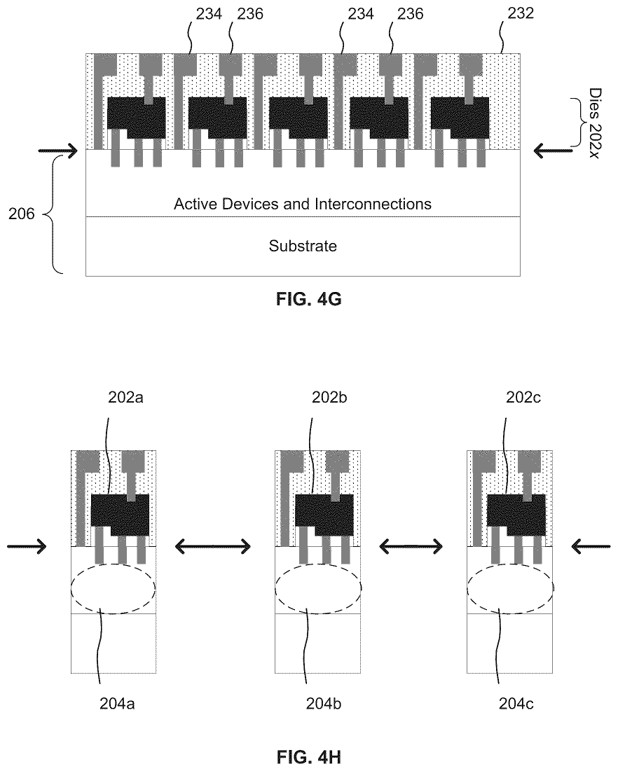

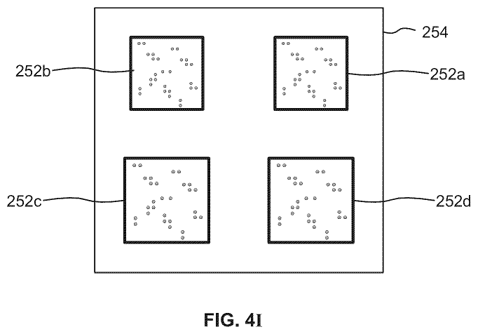

At the outset, it may be useful to understand the end-products resulting from application of one embodiment of the inventive methods. FIG. 2A is a cross-sectional view of a set 200 of pre-singulation 3-D stacked IC dies showing individual die-source IC dies 202a-202e bonded to corresponding recipient-wafer ICs 204a-204e (indicated by dashed ovals) formed on a recipient wafer 206. The recipient-wafer ICs 204a-204e (generically, “204x”) comprise active devices and interconnections 208 formed on a substrate 210. As shown in FIG. 2A, interconnects of die-source IC dies 202x align with mating/corresponding interconnects within the recipient wafer 206 (as also shown in FIG. 4D). FIG. 2B is a cross-sectional view of a set 220 of post-singulation 3-D stacked IC dies showing individual die-source IC dies 202a-202c bonded to corresponding recipient-wafer ICs 204a-204c (indicated by dashed ovals). In both figures, the left and right arrows indicated the bonding plane between the recipient-wafer ICs and the die-source ICs. In some applications, such as wafer-scale integration, the recipient wafer 206 need not be singulated into individual 3-D stacked IC dies. Further details of the structure of the die-source ICs and the recipient-wafer ICs follow.

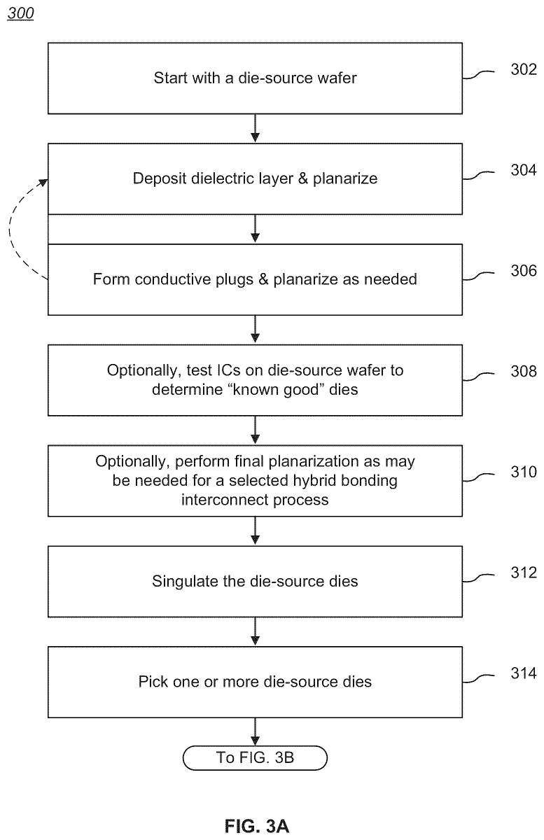

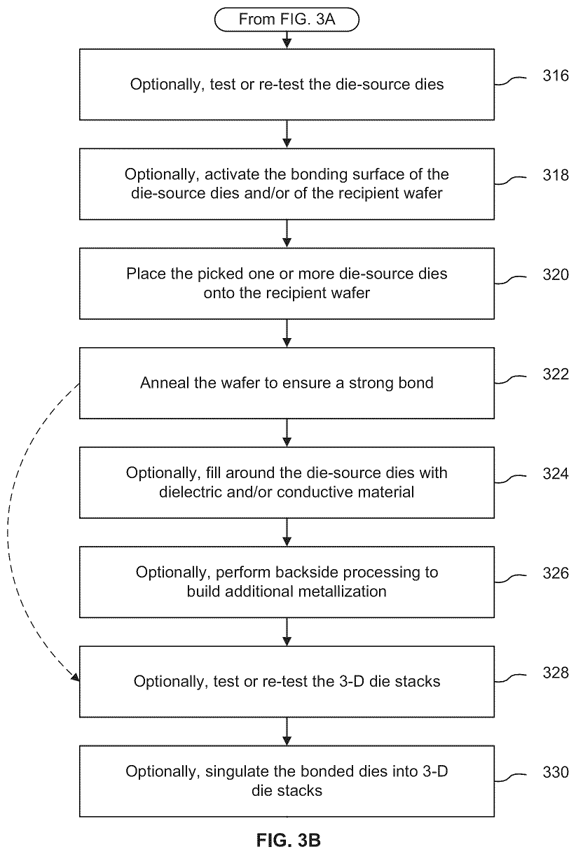

FIGS. 3A-3B are a process flow chart 300 showing one method for fabricating the structures shown in FIGS. 2A and 2B. FIGS. 4A-4I show examples of intermediate stage structures resulting from application of one embodiment of the inventive methods.

In FIG. 3A, the process starts with a die-source wafer [Block 302]. FIG. 4A is a cross-sectional view of a die-source wafer 212 containing multiple complete fabricated die-source IC dies 202a-202c (generically, “202x”) before singulation. The vertical dashed lines 214 indicate the side-to-side boundaries of the individual ICs (5 die-source IC dies are shown by way of example). The die-source wafer 212 may be made from a compound semiconductor material that may include group III-V semiconductor materials such as gallium arsenide (GaAs), gallium nitride (GaN), and indium phosphide (InP), group II-VI semiconductor materials such as cadmium selenide (CdSe), zinc sulfide (ZnS), and zinc telluride (ZnTe), group I-III-VI semiconductor materials, as well as other compound semiconductor materials. The die-source wafer may alternatively comprise a silicon-based material, including bulk silicon, high-resistivity (HR) silicon, silicon-on-insulator (SOI), and silicon-on-sapphire (SOS). For purposes of this example, it is assumed that the die-source wafer 212 is made from GaAs or GaN.

In the illustrated example, the initial die-source wafer 212 may not be sufficiently planar for the requirements of a selected hybrid bonding interconnect (HBI) process. For example, surface irregularities may arise during the fabrication of the die-source ICs as various device and interconnection structures are formed. Further, conductive vias need to be formed to enable connection of the circuitry of the die-source IC dies 202x to the circuitry of corresponding recipient-wafer dies 204x. FIG. 4B is a cross-sectional view of a die-source wafer 212 after deposition of a dielectric layer 216 and formation of conductive vias 218. The dielectric layer 216 may be deposited in known fashion over the die-source wafer 212 and planarized, such as by chemical-mechanical polishing (CMP) [Block 304]. The conductive vias 218 may then be formed, such as by masking and etching, and then planarized as needed, such as by CMP [Block 306]. The material for the conductive vias 218 may be, for example, copper (Cu), but any conductive material compatible with a selected HBI process may be used. The processes shown in Blocks 304 and 306 may be iterated as needed, for example, to form additional vias.

At this point, the individual ICs on the die-source wafer 212 may be tested. Testing at this stage of the process benefits from the die-source IC dies 202x not yet being singulated, so that the entire die-source wafer 212 may be processed through a testing apparatus to determine known-good dies [Block 308]. This can be an important step in that the yield of 3-D stacked IC dies should increase substantially in comparison to a wafer-to-wafer bonding process.

Next, an optional final planarization may be performed as may be needed for a selected hybrid bonding interconnect process [Block 310]. This step may be needed in some cases since testing may create defects/non-uniformities on the surface (e.g., when test probes are pressed against pads). The planarized surface of the die-source wafer 212 may be referenced as a “bonding surface” 220.

The individual die-source IC dies 202x of the planarized, HBI-ready die-source wafer 212 may then be singulated (“diced”) [Block 312]. As one method of singulation, the bonding surface 220 of the die-source wafer 212 may be adhered to a dicing tape (generally by “flipping” the die-source wafer 212 over onto an adhesive dicing tape, as indicated by twisting arrow 222) and the substrate of the die-source wafer 212 may then be subjected to back-grinding to thin the substrate, in known fashion. At that stage, scribing may be by any suitable means, including sawing and/or laser scribing, and the dicing tape expanded to separate the dies. For example, FIG. 4C is a cross-sectional view of singulated die-source IC dies 202x adhered to a dicing tape 224.

FIG. 4D is a cross-sectional view of a die-tape 224 containing multiple die-source IC dies 202x, a “pick and place” apparatus 226, a plasma source 228, and a recipient wafer 206 in the early stages of placing die-source IC dies 202x. FIG. 4E is a cross-sectional view of a recipient wafer 206 on which has been placed multiple die-source IC dies 202x. Referring to FIG. 3A, one or more die-source IC dies 202x may be picked off of the dicing tape 224 using the “pick and place” apparatus 226 [Block 314]. The “pick and place” apparatus 226 may be configured to pick or place one or more dies at a time. Use of a multi-die “pick and place” apparatus capable of picking and placing two or more dies at a time increases throughput. If the die-source IC dies 202.x had previously been tested, only known-good dies need be picked.

Referring to FIG. 3B, the individual die-source IC dies 202x picked from the dicing tape 224 may be tested, either again or for the first time [Block 316]. Testing after singulation enables determination of known-good dies after the stresses of the dicing process. This can be an important step in that the yield of 3-D stacked IC dies should increase substantially in comparison to a wafer-to-wafer bonding process. However, testing may be skipped when the yield of the die-source wafer is known to be sufficiently high.

As an optional process, the bonding surface 220 of a picked die-source IC die 202x may be subjected to a pre-placement process to activate the bonding surface 220 for better adherence to the recipient wafer 206 [Block 318]. Plasma activation of copper conductive vias 218 is known to be particularly useful in providing good bonding of a die to a wafer. In particular, plasma activation reduces the thermal requirements for bond formation when a die is brought into contact with a recipient wafer. As one example of the plasma activation process, an argon plasma may be applied to remove native Cu oxides and surface contaminants, and then a nitrogen plasma may be applied on the Cu surfaces to produce an ultra-thin layer of copper nitride, which has been found to benefit controlling the Cu surface and assisting with low temperature (e.g., room temperature) bonding. In a similar manner and for similar reasons, the bonding surface of a recipient wafer 206 may be plasma activated. Alternatives to plasma activation may include processes such as surface assembled monolayer (SAM), chemical modification, or specialized CMP (e.g., “touch” CMP).

The picked die-source IC dies 202x may then be placed on a bonding surface 229 (see FIG. 4D) of a recipient wafer 206 in alignment with a corresponding recipient-wafer IC 204x [Block 320].

The recipient wafer 206 may comprise, for example, a compound semiconductor material or a silicon-based material, and may embody active devices (e.g., transistors, diodes) and/or passive devices (e.g., inductors, resistors, capacitors). Note that the recipient wafer 206 and the die-source wafer 212 need not be (but may be) made from the same material, and that the die-source wafer 212 may be of a different size (e.g., 150 mm diameter) than the recipient wafer 206 (e.g., 300 mm diameter).

In general, some pressure is applied during placing to create a bond between a placed die-source IC die 202x and the corresponding recipient-wafer IC 204x, such as about 10 N of force for about 10 seconds. Bonds between the dielectric layer 216 of the placed die-source IC die 202x and corresponding dielectric regions of the recipient-wafer IC 204x, and between the conductive vias 218 of the placed die-source IC die 202x and corresponding conductive vias 230 of the recipient-wafer IC 204x (see FIG. 4D) generally form at ambient temperature. Stronger bonds may form at room temperature, but generally only over a very long period of time. Accordingly, to increase throughput, the recipient wafer 206 and its bonded die-source IC dies 202x are preferably subjected to an annealing step to ensure a strong bond [Block 322]. For example, annealing may be at a temperature of between about 200-450° C. for a few minutes to a few hours (e.g., two hours). Annealing does not have to follow placing immediately.

Once strong bonding is completed, in some applications, the bonded 3-D die stacks may be singulated and directed to their ultimate use. For such applications, the bonded 3-D die stacks may be tested, either again or for the first time [Block 328] and then singulated [Block 330]
see the dashed-arrow pathway in FIG. 3B. However, for many applications, it may be useful to fill around the die-source IC dies 202x with dielectric and/or conductive material [Block 324]. For example, FIG. 4F is a cross-sectional view of a recipient wafer 206 on which has been bonded multiple die-source IC dies 202x. The bonded die-source IC dies 202x are shown encapsulated by a fill material 232, which may be chosen from multiple types of dielectrics and/or conductors known in the art.

If a fill is used, in some applications, it may be useful to perform backside processing to form additional metallization connections on and/or through the fill material [Block 326]. FIG. 4G is a cross-sectional view of a recipient wafer 206 on which has been bonded multiple die-source IC dies 202x encapsulated by a fill material 232. Conductive connections, such as vias and horizontal traces, may be formed using conventional back-end of line (BEOL) processes. In FIG. 4G, connections 234 are to the recipient-wafer ICs 204x, and connections 236 are to the die-source IC dies 202x (not all connections are labeled to avoid clutter).

Optionally, the bonded 3-D die stacks may be tested, either again or for the first time [Block 328].

In some applications, such as wafer-scale integration, the recipient wafer 206 with bonded die-source IC dies 202x need not be singulated. However, in general, the 3-D stacked IC dies comprising die-source IC dies 202x bonded to corresponding recipient-wafer ICs 204x will be singulated [Block 330] and directed to their ultimate use. For example, FIG. 4H is a cross-sectional view of a set of post-singulation 3-D stacked IC dies showing individual die-source IC dies 202a-202c bonded to corresponding recipient-wafer ICs 204a-204c (indicated by dashed ovals).

It should be noted that a one-to-one correspondence of die-source IC dies to recipient-wafer ICs is not required. For example, in some applications, two or more die-source IC dies 202x may be bonded to one recipient-wafer IC 204x. This may be useful, for example, were a recipient-wafer IC 204x embodies low-power control and driver circuitry (e.g., Si-CMOS) capable of operating multiple radio frequency components (e.g., power amplifiers, low-noise amplifiers, filters, switches, etc.) embodied in two or more die-source IC dies 202x (e.g., GaAs or GaN) which, for example, may be configured to have different operating characteristics. For example, FIG. 4I is a top plan view of four die-source IC dies 252a-252d bonded on a single recipient-wafer IC 254. In this example, a first two of the die-source IC dies 252a-252b are shown as smaller in size than a second two of the die-source IC dies 252c-252d, illustrating another advantage of die-to-wafer bonding: the bonded dies may be of different types and/or sizes, and from different die-source wafers.

### Die Alignment Structures

A critical aspect of an economically viable HBI technology is the ultimate yield of 3-D stacked IC dies, and one critical determinate of yield is alignment of die-source IC dies 202x to recipient-wafer ICs 204x. Misalignment is mainly generated during the HBI bonding step and may be caused by a shift in rotation (primarily yaw) and/or X-Y axis offsets between a die-source IC die 202x and a corresponding recipient-wafer IC 204x. As noted above, a problem with current die-to-wafer bonding technologies is that the alignment accuracy is only about 5-10 μm compared to an alignment accuracy of about 1 μm for wafer-to-wafer bonding.

To mitigate the alignment problem, embodiments of the present invention may beneficially utilize alignment or guiding structures formed as part of the recipient wafer 206 (or recipient-wafer ICs 204x) and/or the die-source IC dies 202x. In general, alignment structures are physical modifications that provide guidance and/or engagement of a die-source IC die 202x with respect to a corresponding recipient-wafer IC 204x in order to reduce relative misalignment between the two ICs. Embodiments of the present invention that utilize alignment structures may improve the alignment between two such ICs by as much as 2 μm.

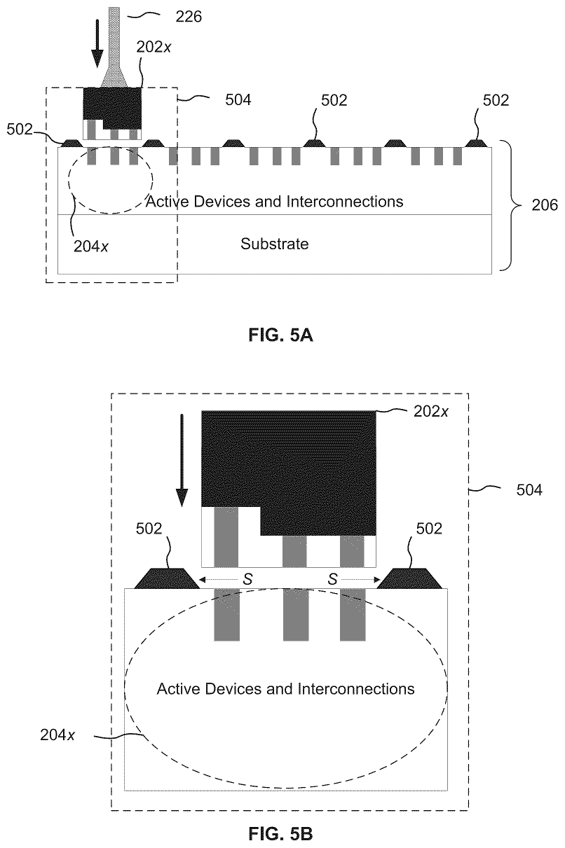

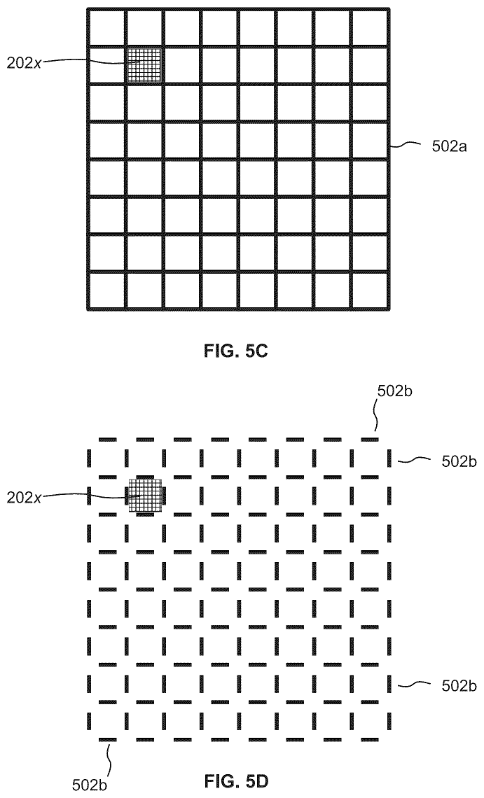

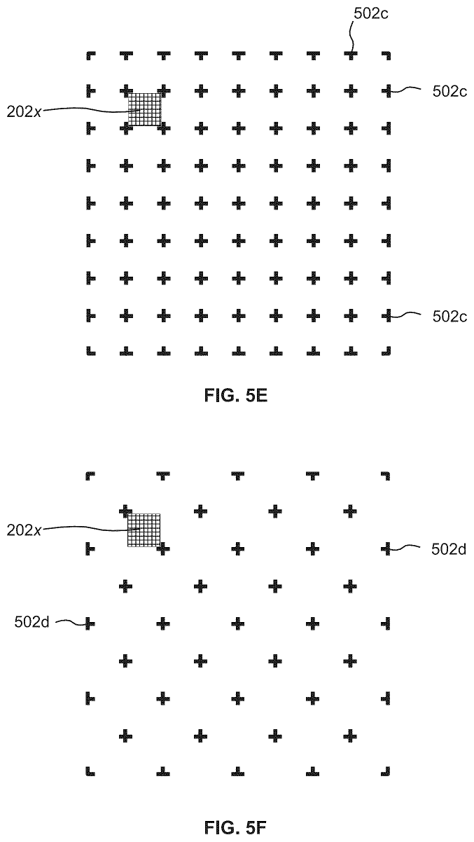

FIG. 5A is a cross-sectional view of a recipient wafer 206 having one embodiment of alignment structures 502 designed to guide placement of a die-source IC die 202x with respect to a corresponding recipient-wafer IC 204x. FIG. 5B is a closeup view of a portion 504 of FIG. 5A. In the illustrated example, the alignment structures 502 are configured to physically guide and align a die-source IC die 202x by interference as the die-source IC die 202x is placed in contact with a corresponding recipient-wafer IC 204x by a “pick and place” apparatus 226 (not shown in FIG. 5B). It is advantageous for the alignment structures 502 to have some slope or bevel to the side surfaces S that the edges of the die-source IC die 202x may contact as the “pick and place” apparatus 226 moves the die-source IC die 202x into bonding engagement with the corresponding recipient-wafer IC 204x. Interference by the sloped side surfaces as the die-source IC die 202x approaches bonding contact provides rotational and/or translational movement to the die-source IC die 202x to better orient the rotational and X-Y position of the die-source IC die 202x relative to the recipient-wafer IC 204x. As should be apparent, the alignment structures 502 enable the die-source IC die 202x to self-align with respect to the recipient-wafer IC 204x. The result is a substantial improvement in the alignment between the two ICs by as much as 2 μm.

A number of different bonding-surface patterns may be used to define the alignment structures 502 on the bonding surface of a recipient wafer 206. For example, FIG. 5C is a top plan view of a first embodiment of an alignment structure pattern defining a grid structure 502a that would border and contact all sides of a die-source IC die 202x. FIG. 5D is a top plan view of a second embodiment of an alignment structure pattern defining edge-engagement structures 502b that would contact only part of the edges of a die-source IC die 202x. FIG. 5E is a top plan view of a third embodiment of an alignment structure pattern defining corner-engagement structures 502c that would contact only the four corners of a die-source IC die 202x. FIG. 5F is a top plan view of a fourth embodiment of an alignment structure pattern defining “sparse” corner-engagement structures 502d that would contact only two opposite corners of a die-source IC die 202x. As should be appreciated, other patterns (including combinations of patterns) of alignment structures may be defined to provide similar functionality regarding enabling a die-source IC 202x to self-align with respect to a recipient-wafer IC 204x during the placement process.

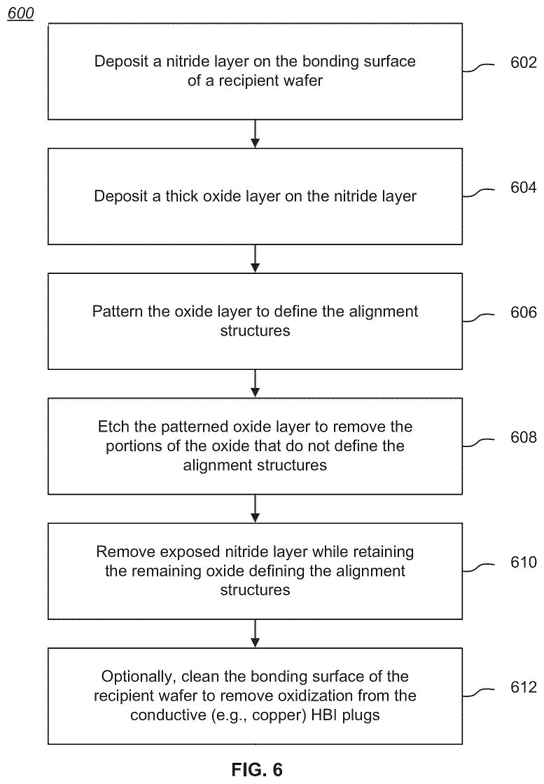

The alignment structures 502 may be formed on the bonding surface of a recipient wafer 206 in several ways, and it is generally beneficial to select a method that is compatible with common BEOL processes. For example, FIG. 6 is a process flow chart 600 showing one method for forming alignment structures 502. In an embodiment, one may include depositing a nitride layer on the bonding surface of a recipient wafer [Block 602], followed by a thick oxide layer [Block 604]. The nitride layer may also be the actual patterned layer used to form the alignment structures 502. In both cases, the nitride layer may be patterned using, for example, a conventional lithography step. The nitride layer may also act as an etch stop. The nitride may also serve as a hard mask. The thickness of the oxide layer determines the height of the alignment structure 502 above the bonding surface 229 of the recipient wafer 206 (and thus of recipient-wafer ICs 204x), and may be, for example, about a micron to few tens of microns.

The oxide layer is patterned (e.g., with a photomask or a hard-mask deposit, such as a nitride deposit) to define the alignment structures 502 [Block 606], and the patterned oxide layer is then etched down to the nitride layer (from [Block 602]) to remove the portions of the oxide that do not define the alignment structures 502 [Block 608]. The exposed nitride layer may then be removed, typically by an etchant (e.g., hot phosphoric acid) or process that is very selective with respect to retaining the remaining oxide defining the alignment structures 502 (and in some cases, a previous thin oxide layer protecting the metal contacts of the receiving wafer) [Block 610]. (Such a thin oxide layer will allow bonding after plasma activation, and should be thin enough to permit copper to go through when the annealing step is performed, creating the contact between the metals of the two dies by breaking through the thin oxide layer).

Optionally, as a post-formation step, the bonding surface of the recipient wafer 206, now bearing the alignment structures 502 in places, may be cleaned to remove oxidation from the surfaces of conductive (e.g., copper) HBI vias [Block 612].

As should be appreciated, a number of other materials and processes may be used in known fashion to form the alignment structures 502, including polyimide-based alignment structures 502.

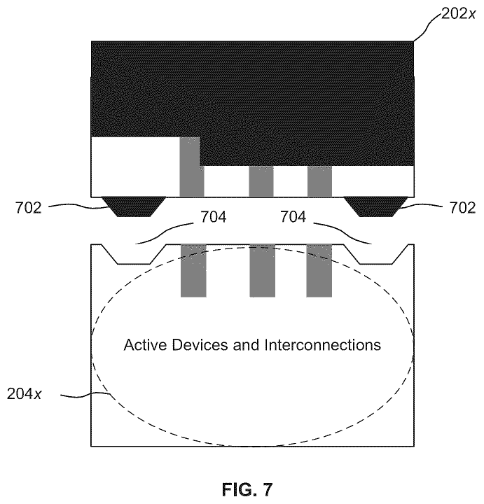

The raised alignment structures 502 shown in FIGS. 5A and 5B provide for guidance of a die-source IC die 202x with respect to a corresponding recipient-wafer IC 204x by sideways interference in order to reduce relative misalignment between the two ICs. In alternative embodiments, alignment structures may be formed on both the die-source IC dies 202x and the recipient-wafer IC 204x to provide for positive engagement of the two dies—a form of “lock and key” arrangement. For example, FIG. 7 is a cross-sectional view of a die-source IC die 202x and a recipient-wafer IC 204x configured with complementarily-shaped alignment structure projections 702 and depressions 704. While FIG. 7 shows the projections 702 as being formed on the bonding surface of the die-source IC die 202x and the depressions 704 as being formed on the bonding surface of the recipient-wafer IC 204x, the locations of the two alignment structure elements may be reversed. The projections 702 may be formed in the manner described in FIG. 6 or any other convenient process and may be formed in any of the patterns shown in FIGS. 5C-5F. The depressions 704 may be formed by conventional masking and etching techniques known in the art and may be formed in any of the patterns shown in FIGS. 5C-5F. It is advantageous for the alignment structure projections 702 and depressions 704 to have some slope to their respective side surfaces to improve mutual alignment.

### General Benefits

Embodiments of the invention generally provide one or more of the following advantages (noting that the list is not exhaustive):
Reduced power consumption when using high-performance die-source IC dies (e.g., power amplifiers, LNAs, high-speed switches, etc., based on group III-V semiconductor materials such as GaAs or GaN) with low-power recipient-wafer ICs (e.g., CMOS on SOI for baseband transceiver controller/logic);
Compact 3-D stacked IC dies having a reduced 2-D planar “footprint” and reduced die-to-die routing lengths (beneficially reducing RF interference and/or distortion);
Improved thermal performance (and power efficiency) through relatively short thermal conductive paths within the 3-D stacked IC dies;
Multiple process points for testing for known-good dies, which improves yield;
Higher yields of 3-D stacked IC dies by winnowing out defective dies before bonding; and
Higher yields of 3-D stacked IC dies by improving alignment of die-source IC dies 202x and corresponding recipient-wafer ICs 204x during bonding.

### Circuit Embodiments

Circuits and devices in accordance with the present invention may be used alone or in combination with other components, circuits, and devices. Embodiments of the present invention may be encased in IC packages and/or in modules for ease of handling, manufacture, and/or improved performance. In particular, 3-D stacked IC die embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

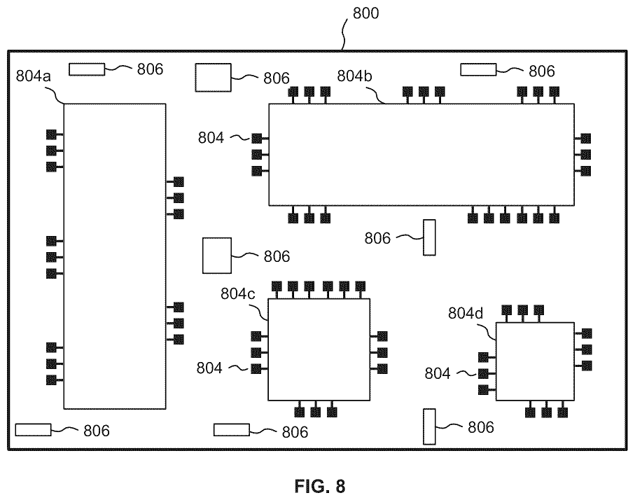

As one example of further integration of embodiments of the present invention with other components, FIG. 8 is a top plan view of a substrate 800 that may be, for example, a printed circuit board or chip module substrate (e.g., a thin-film tile). In the illustrated example, the substrate 800 includes multiple ICs 802a-802d—any of which may be a 3-D stacked IC—having terminal pads 804 which would be interconnected by conductive vias and/or traces on and/or within the substrate 800 or on the opposite (back) surface of the substrate 800 (to avoid clutter, the surface conductive traces are not shown and not all terminal pads are labelled). The ICs 802a-802d may embody, for example, signal switches, active filters, amplifiers (including one or more LNAs), and other circuitry.

The substrate 800 may also include one or more passive devices 806 embedded in, formed on, and/or affixed to the substrate 800. While shown as generic rectangles, the passive devices 806 may be, for example, filters, capacitors, inductors, transmission lines, resistors, planar antennae elements, transducers (including, for example, MEMS-based transducers, such as accelerometers, gyroscopes, microphones, pressure sensors, etc.), batteries, etc., interconnected by conductive traces on or in the substrate 800 to other passive devices 806 and/or to the individual ICs 802a-802d.

The front or back surface of the substrate 800 may be used as a location for the formation of other structures. For example, one or more antennae (not shown) may be formed on or affixed to the front or back surface of the substrate 800. Thus, by including one or more antennae on the substrate 800, a complete radio receiver, transmitter, or transceiver may be created.

### System Aspects

Embodiments of the present invention are useful in a wide variety of larger radio frequency (RF) circuits and systems for performing a range of functions, including (but not limited to) impedance matching circuits, RF power amplifiers, RF low-noise amplifiers (LNAs), phase shifters, attenuators, antenna beam-steering systems, charge pump devices, RF switches, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, 6G, and WiFi (e.g., 802.11a, b, g, ac, ax, be) protocols, as well as other radio communication standards and protocols.

As discussed above, the current invention reduces power consumption, reduces the 2-D planar “footprint”, improves thermal performance, and improves yield of 3-D stacked IC dies through pre-testing of die-source IC dies and improving die alignment during HBI bonding. As a person of ordinary skill in the art will understand, a system architecture is beneficially impacted by the current invention in critical ways, including lower power, longer battery life, smaller size, lower cost, etc. These system-level improvements are specifically enabled by the current invention. The current invention therefore specifically encompasses higher level systems that are creatively enabled by inclusion of embodiments of the present invention in such systems.

Fabrication Technologies & Options

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or combinations of such technologies. Embodiments of the die-source IC dies and recipient-wafer ICs may be fabricated using any suitable substrates and processes, including but not limited to standard bulk silicon, high-resistivity bulk CMOS, silicon-on-insulator (SOI), and silicon-on-sapphire (SOS), as well as other transistor technologies such as bipolar, BiCMOS, LDMOS, BCD, GaAs HBT, GaN HEMT, GaAs pHEMT, and MESFET technologies.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

### CONCLUSION

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

What is claimed is:

1. A method of fabricating 3-D stacked integrated circuit (IC) dies, the method including:
(a) fabricating die-source IC dies on a die-source wafer;
(b) forming conductive vias on a bonding surface of each die-source IC die;
(c) singulating the die-source IC dies;
(d) testing the die-source IC dies before and/or after singulating the die-source IC dies to determine known-good die-source IC dies;
(e) picking known-good die-source IC dies from the singulated dies;
(f) contacting the picked known-good die-source IC dies to corresponding recipient-wafer ICs formed as part of a recipient wafer, thereby bonding the known-good die-source IC dies to the corresponding recipient-wafer ICs on the recipient wafer to form 3-D stacked IC dies; and
(g) forming alignment structures on a bonding surface of the recipient wafer, the alignment structures shaped and positioned to guide placement of the picked known-good die-source IC dies with respect to the corresponding recipient-wafer ICs.

2. The method of claim 1, wherein the alignment structures have sloped side surfaces that may be contacted by edges of the picked known-good die-source IC dies.

3. The method of claim 2, further including forming the alignment structures in one of: a grid pattern configured to border and contact all sides of the picked known-good die-source IC dies, an edge-engagement pattern configured to contact only part of the edges of the picked known-good die-source IC dies, a corner-engagement pattern configured to contact only the four corners of the picked known-good die-source IC dies, or a sparse corner-engagement pattern configured to contact only two opposite corners of the picked known-good die-source IC dies.

4. The method of claim 1, further including forming the alignment structures in a grid pattern configured to border and contact all sides of the picked known-good die-source IC dies.

5. The method of claim 1, further including forming the alignment structures in an edge-engagement pattern configured to contact only part of the edges of the picked known-good die-source IC dies.

6. The method of claim 1, further including forming the alignment structures in a corner-engagement pattern configured to contact only the four corners of the picked known-good die-source IC dies.

7. The method of claim 1, further including forming the alignment structures in a sparse corner-engagement pattern configured to contact only two opposite corners of the picked known-good die-source IC dies.

8. A 3-D stacked integrated circuit (IC) die including:
(a) a die-source IC die including a bonding surface and conductive vias; and
(b) a recipient-wafer IC die including:
(1) a bonding surface and conductive vias in aligned contact with the bonding surface and conductive vias of the die-source IC die; and
(2) an alignment structure formed on the bonding surface of the recipient-wafer IC die and shaped and positioned to guide placement of the bonding surface and conductive vias of the die-source IC die into bonding engagement with the bonding surface and conductive vias of the recipient-wafer IC die.

9. The invention of claim 8, wherein the alignment structure has sloped side surfaces that may be contacted by edges of the die-source IC die.

10. The invention of claim 9, wherein the alignment structure is configured as one of: a grid pattern configured to border and contact all sides of the die-source IC die, an edge-engagement pattern configured to contact only part of the edges of the die-source IC die, a corner-engagement pattern configured to contact only the four corners of the die-source IC die, or a sparse corner-engagement pattern configured to contact only two opposite corners of the die-source IC die.

11. The invention of claim 8, wherein the alignment structure is configured in a grid pattern configured to border and contact all sides of the die-source IC die.

12. The invention of claim 8, wherein the alignment structure is configured in an edge-engagement pattern configured to contact only part of the edges of the die-source IC die.

13. The invention of claim 8, wherein the alignment structure is configured in a corner-engagement pattern configured to contact only the four corners of the die-source IC die.

14. The invention of claim 8, wherein the alignment structure is configured in a sparse corner-engagement pattern configured to contact only two opposite corners of the die-source IC die.

15. The invention of claim 8, wherein the die-source IC die is formed from a compound semiconductor material die-source wafer.

16. The invention of claim 8, wherein the die-source IC die is formed from a silicon-based die-source wafer.

17. The invention of claim 8, wherein the die-source IC die is formed from a gallium arsenide or gallium nitride die-source wafer.

18. The invention of claim 8, wherein the recipient-wafer IC die is formed on a compound semiconductor material recipient wafer.

19. The invention of claim 8, wherein recipient-wafer IC die is formed on a silicon-based recipient wafer.

20. The invention of claim 8, wherein the recipient-wafer IC die includes CMOS circuits formed on a silicon-on-insulator recipient wafer.
